(19) United States
(12) Patent Application Publication
(10) Pub. No.: US 2024/0365675 A1
(43) Pub. Date: Oct. 31, 2024

(54) MRAM WITH ASYMMETRIC STRUCTURE

(71) Applicant: INTERNATIONAL BUSINESS MACHINES CORPORATION, ARMONK, NY (US)

(72) Inventor: Daniel Worledge, San Jose, CA (US)

(21) Appl. No.: 18/307,034

(22) Filed: Apr. 26, 2023

(51) Int. Cl. H10N 50/10; H01L 23/522; H01L 23/528; H10B 61/00; H10N 50/85

(52) U.S. Cl. CPC H10N 50/10; H01L 23/5226; H01L 23/5283; H10B 61/00; H10N 50/85

(57) ABSTRACT

Embodiments of present invention provide a MRAM structure. The structure includes a metallic wire, the metallic wire having a width between a first side and a second side; a length between a first end and a second end; and a lengthwise axis, and being symmetric with respect to the lengthwise axis; a conductive via contacting a first area of the metallic wire; and a magnetic tunnel junction (MTJ) stack placed at a second area of the metallic wire. The MRAM structure is asymmetric with respect to the lengthwise axis to have a second metallic wire formed at the first side of the metallic wire or have the MTJ stack placed asymmetric with respect to the lengthwise axis. A method of forming the MRAM structure is also provided.

### BACKGROUND

The present application relates to manufacturing of semiconductor integrated circuits. More particularly, it relates to structure of a spin-orbit torque magnetoresistive random-access memory and method of manufacturing the same.

With the explosion of digital information, semiconductor memory devices are playing an increasingly important role in the managing and organizing of this digital information in the area of, for example, storing, retrieving, and/or transforming of this digital information. Magnetoresistive random-access memory (MRAM) is a type of non-volatile memory (NVM) that is capable of holding saved data even in the event that power to the memory device is down or accidentally cut off.

MTJ technology is based on a component known as magnetic tunnel junction (MTJ) stack that consists of a reference layer, a tunnel barrier layer, and a free layer. A spin-orbit torque MRAM applies the use of a spin-orbit torque (SOT) wire to further enhance the MRAM performance. During operation, the SOT wire generates spins that are subsequently collected by the MTJ stack thereby enhancing performance of the MRAM. However, there remains a research topic as to how to effectively generate spins, particularly useful spins, and how these useful spins may be efficiently collected.

### SUMMARY

Embodiments of present invention provide a MRAM structure. The structure includes a metallic wire, the metallic wire having a width between a first side and a second side; a length between a first end and a second end; and a lengthwise axis, and being symmetric with respect to the lengthwise axis; a conductive via contacting a first area of the metallic wire; and a magnetic tunnel junction (MTJ) stack placed at a second area of the metallic wire, where the MRAM structure is asymmetric with respect to the lengthwise axis.

According to one embodiment, the metallic wire is a first metallic wire, and the structure further includes a second metallic wire formed next to the first side of the first metallic wire. In one embodiment, the first metallic wire includes a metal having an atomic number greater than 54, and the second metallic wire includes a metal having an atomic number less than 30. In another embodiment, the first metallic wire is made of a material selected from a group consisting of tungsten (W), platinum (Pt), and tantalum (Ta), and the second metallic wire is made of a material selected from a group consisting of aluminum (Al) and copper (Cu).

In one embodiment, the MTJ stack includes a free layer, a tunnel barrier layer on top of the free layer, and a reference layer on top of the tunnel barrier layer, where the free layer is placed on at least one of the first and the second metallic wire.

According to another embodiment, the first metallic wire includes tungsten (W), platinum (Pt), or tantalum (Ta), and the second metallic wire includes niobium (Nb).

In one embodiment, the structure further includes an electrically insulating spin-conductor on top of the first and the second metallic wire, and a metallic spin-conductor on top of the electrically insulating spin-conductor, where the electrically insulating spin-conductor covers a portion of the first metallic wire and a portion of the second metallic wire that is adjacent to the portion of the first metallic wire.

In another embodiment, the MTJ stack is placed above the metallic spin-conductor and a portion of the metallic spin-conductor underneath the MTJ stack is in direct contact with the first and the second metallic wire.

According to yet another embodiment, the structure further includes a metallic stud at an end of the metallic spin-conductor, where the metallic stud contacts the metallic spin-conductor; the first metallic wire; and the second metallic wire.

In one embodiment, the electrically insulating spin-conductor includes nickel oxide (NiO) and the metallic spin-conductor includes copper (Cu).

In one embodiment, the conductive via and the MTJ stack are symmetrically placed with respect to the lengthwise axis of the metallic wire.

In another embodiment, the MTJ stack is placed substantially close to or over an edge at the first side of the metallic wire and covers less than one half of the width of the metallic wire.

In one embodiment, the metallic wire is embedded in a dielectric layer, the dielectric layer covering the first and the second side of the metallic wire.

According to one embodiment, the structure further includes an electrically insulating spin-conductor and a metallic spin-conductor on top of the electrically insulating spin-conductor, the electrically insulating spin-conductor covering the edge at the first side of the metallic wire.

According to another embodiment, the structure further includes a high resistance spin-conductor covering the edge at the first side of the metallic wire.

In one embodiment, the metallic wire is not straight and includes one or more bends from the first end to the second end.

Embodiments of present invention provide a MRAM structure. The structure includes a bimetallic wire having a first and a second metallic wire formed side-by-side; a conductive via contacting a first area of the bimetallic wire; and a magnetic tunnel junction (MTJ) stack contacting a second area of the bimetallic wire, where the first metallic wire comprises a first metal element having an atomic number greater than 54, and the second metallic wire comprises a second metal element having an atomic number less than 30.

Embodiments of present invention provide a MRAM structure. The structure includes a bimetallic wire having a first and a second metallic wire formed side-by-side; a conductive via contacting a first area of the bimetallic wire; and a magnetic tunnel junction (MTJ) stack contacting a second area of the bimetallic wire, where the first metallic wire is made of tungsten (W), platinum (Pt), or tantalum (Ta), and the second metallic wire is made of copper (Cu) or aluminum (AI).

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, and 1C-FIGS. 5A, 5B, and 5C are demonstrative illustrations of side views and top views of MRAM devices according to some embodiments of present invention;

FIGS. 6A, 6B, 6C, and 6D are top views of MRAM devices according to some embodiments of present invention;

FIGS. 7A, 7B, and 7C-FIGS. 9A, 9B, and 9C are demonstrative illustrations of side views and top views of MRAM devices according to some embodiments of present invention;

FIGS. 10A, 10B, and 10C are side views of MRAM devices according to some embodiments of present invention;

FIGS. 11A, 11B, and 11C are top views of MRAM devices according to some embodiments of present invention;

FIG. 12 is a top view of a MRAM device according to one embodiment of present invention; and

FIG. 13A-13E are demonstrative illustrations of cross-sectional views of a MRAM at various manufacturing steps according to another embodiment of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

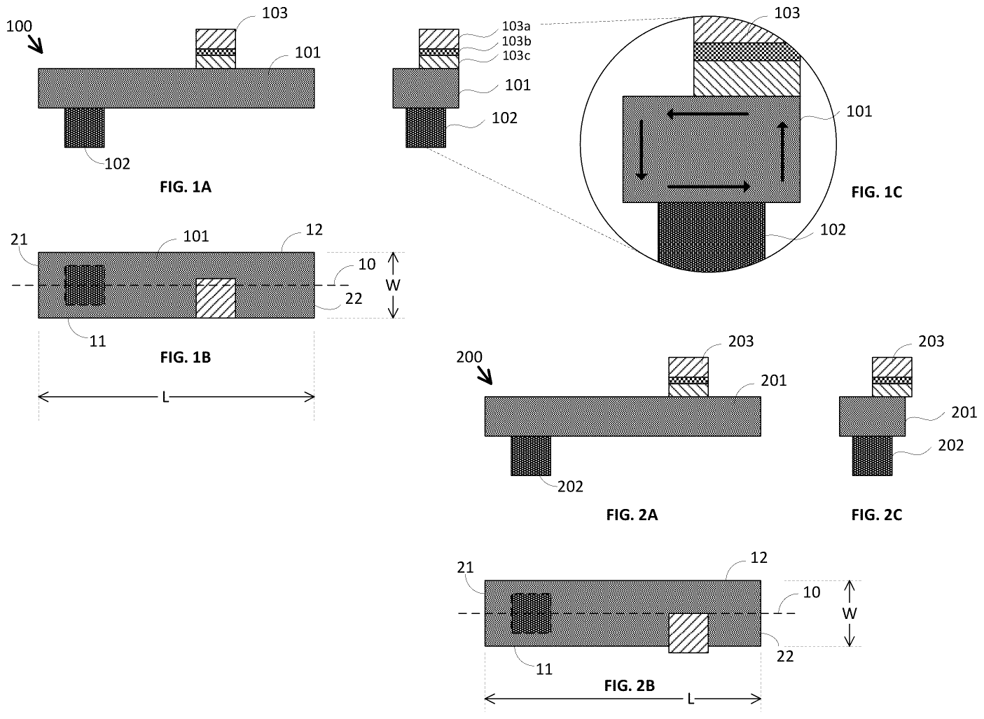

FIGS. 1A, 1B, and 1C are demonstrative illustrations of a MRAM device according to one embodiment of present invention. More particularly, FIG. 1A is a front side view, FIG. 1B is a top view, and FIG. 1C is a left side view of a MRAM device 100. As is illustrated in the top view in FIG. 1B, the MRAM device 100 may include a metallic wire 101 having a width W between a first side 11 and a second side 12; a length L between a first end 21 and a second end 22; and a lengthwise axis 10. The metallic wire 101 is symmetric with respect to the lengthwise axis 10.

The MRAM device 100 may further include a conductive via 102 contacting a first area of the metallic wire 101, and a MTJ stack 103 contacting a second area of the metallic wire 101. The MTJ stack 103 may include a free layer 103c, a tunnel barrier layer 103b on top of the free layer 103c, and a reference layer 103a on top of the tunnel barrier layer 103b.

According to one embodiment, structurally the MRAM device 100 may be asymmetric with respect to the lengthwise axis 10, as is illustrated in the top view in FIG. 1B. For example, embodiments of present invention provide placing the MTJ stack 103 closer to one side of the metallic wire 101, such as the first side 11, for an asymmetric placement of the MTJ stack 103 with respect to the lengthwise axis 10, thereby resulting in the MRAM device 100 that is structurally asymmetric with respect to the lengthwise axis 10 of the metallic wire 101.

By placing the MTJ stack 103 closer to the first side 11 of the metallic wire 101, embodiments of present invention enables the MTJ stack 103 to collect more perpendicular spins from the metallic wire 101, which is for example a spin-orbit-torque (SOT) wire. As is demonstratively illustrated in the expanded portion of FIG. 1C, during normal operation when electrical current is flowing (into the paper) from the conductive via 102 towards the MTJ stack 103, spins of electrons generally line up in a counterclockwise direction with more perpendicular spins at the first (right) side 11 and the second (left) side 12 of the metallic wire 101. Being placed at the first (right) side 11 of the metallic wire 101, the MTJ stack 103 will be able to collect more upwardly perpendicular spins, which helps in aligning the free layer 103c with the reference layer 103a in the MTJ stack 103 thereby enhancing performance of the MRAM device 100. The horizontal spins, at the top and bottom sides of the metallic wire 101, are generally less useful in terms of improving the MRAM device performance.

FIGS. 2A, 2B, and 2C are demonstrative illustrations of a MRAM device according to one embodiment of present invention. More particularly, FIG. 2A is a front side view, FIG. 2B is a top view, and FIG. 2C is a left side view of a MRAM device 200. Similar to the MRAM device 100, the MRAM device 200 has a metallic wire 201 that has a width W between a first side 11 and a second side 12; a length L between a first end 21 and a second end 22; and a lengthwise axis 10. The metallic wire 201 is symmetric with respect to the lengthwise axis 10. However, the MRAM device 200 is structurally asymmetric with respect to the lengthwise axis 10 by the placement of, for example, a MTJ stack 203. For example, when being compared with the MRAM device 100, the MTJ stack 203 in the MRAM device 200 is placed at a second area over an edge at the first side 11 of the metallic wire 201. The MTJ stack 203 covers less than, or at most equal to, half of the width W of the metallic wire 201. The MRAM device 200 further includes a conductive via 202 placed at a first area of the metallic wire 201.

The MTJ stack 203 may include a free layer, a tunnel barrier layer, and a reference layer as in the MTJ stack 103. However, for the simplicity of illustration, the free layer, the tunnel barrier layer, and the reference layer of the MTJ stack 203 are not individually labelled and the same may be applied to MTJ stacks of other MRAM devices illustrated in subsequent drawings.

By placing the MTJ stack 203 over the edge and in particular covering less than half of the width W of the metallic wire 201, the MTJ stack 203 is able to avoid collecting downwardly perpendicular spins that are generally at the second (left) side 12 of the metallic wire 201. In the event that downwardly perpendicular spins are collected, they may cancel the effect of the upwardly perpendicular spins collected by the MTJ stack 203 thereby weakening the overall effect of the spin-orbit-torque on the MRAM device performance. In other word, embodiments of present invention provide the MRAM device 200 with a structure that will reduce the collection of downwardly perpendicular spins to avoid their cancellation effect on the upwardly perpendicular spins, thereby enhancing the impact of the upwardly perpendicular spins on the MRAM device performance.

In the above description, it is assumed that the current is injected into the paper, in FIG. 1C and in FIG. 2C, to generate upwardly perpendicular spins to write the free layer of the MTJ stack into an up state. However, when the current is reversed to flow (out of the paper) from the MTJ stack to the conductive via, downwardly perpendicular spins are generated at the first (right) side 11 of the metallic wire 101 and 201. In other words, the spins will reverse direction compared with when the current is injected into the paper. The downwardly perpendicular spins are then collected by the free layer of the MTJ stack which writes the free layer in a down state. Hereinafter, for the ease of description of embodiments, the current is generally assumed to be flow into the paper, from the conductive via to the MTJ stack. As is described above, similar description may be applied when the current is reversed to flow out of the paper from the MTJ stack to the conductive via.

FIGS. 3A, 3B, and 3C are demonstrative illustrations of a MRAM device according to one embodiment of present invention. More particularly, FIG. 3A is a front side view, FIG. 3B is a top view, and FIG. 3C is a left side view of a MRAM device 300. Similar to the MRAM device 100 and 200, the MRAM device 300 has a metallic wire 301 that has a width W between a first side 11 and a second side 12; a length L between a first end 21 and a second end 22; and a lengthwise axis 10. The metallic wire 301 is symmetric with respect to the lengthwise axis 10. Here in FIG. 3B and in subsequent drawings, for the simplicity of illustration, the width W and length L are not particularly illustrated in the drawings.

When being compared with the MRAM device 200, in addition to a conductive via 302 and a MTJ stack 303, the MRAM device 300 further includes a spin-conductor layer 304 of high resistance that covers approximate half of the metallic wire 301 at the first side 11 of the metallic wire 301. The spin-conductor layer 304 may be placed directly underneath the MTJ stack 303 and may be a layer of graphene formed through a chemical-vapor-deposition (CVD) process. In one embodiment, the spin-conductor layer 304 may be a layer of “dirty” copper. Here, “dirty” copper means a copper doped with a small amount (e.g., around 0.1% to 5% ATM) of another element of low atomic number so as to substantially increase resistivity of the copper (e.g., by a factor of 10) without decreasing its spin diffusion length too much (e.g., by a factor of 2). The spin-conductor layer 304 is then patterned to cover approximate half of the metallic wire 301 at the first (right) side 11 of the metallic wire 301. The spin-conductor layer 304 may pass the upwardly perpendicular spins onto the MTJ stack 303, that is, may allow the MTJ stack 303 to collect the upwardly perpendicular spins. In the meantime, because of the high resistance nature, the spin-conductor layer 304 may restrict or prevent electronic current from exiting the metallic wire 301 “prematurely”, thereby increasing and/or maximizing the time and/or duration for the electronic current to generate upwardly perpendicular spins, while propagating along the metallic wire 301, which may be used in aligning the free layer with the reference layer in the MTJ stack for enhancing the MRAM device performance.

FIGS. 4A, 4B, and 4C are demonstrative illustrations of a MRAM device according to one embodiment of present invention. More particularly, FIG. 4A is a front side view, FIG. 4B is a top view, and FIG. 4C is a left side view of a MRAM device 400. Similar to the MRAM device 100, 200, and 300, the MRAM device 400 has a metallic wire 401 that has a width W between a first side 11 and a second side 12; a length L between a first end 21 and a second end 22; and a lengthwise axis 10. The metallic wire 401 is symmetric with respect to the lengthwise axis 10.

When being compared with the MRAM device 200, in addition to a conductive via 402 and a MTJ stack 403, the MRAM device 400 includes an electrically insulating spin-conductor layer 404 that covers approximate half of the metallic wire 401 at the first side 11 of the metallic wire 401. The MRAM device 400 further includes a metallic spin-conductor layer 405 of low resistance, on top of the electrically insulating spin-conductor layer 404, and a metal stud 406 at the end of the metallic spin-conductor layer 405. The metal stud 406 may contact the metallic wire 401 at its second end 22.

The electrically insulating spin-conductor layer 404 may be a layer of nickel-oxide (NiO), for example, that has low “resistance” to spins of electrons but high resistance to electronic current. The metallic spin-conductor layer 405 may be a low resistance metallic layer such as, for example, copper (Cu). The metallic spin-conductor layer 405 may pass perpendicular spins, collected through the electrically insulating spin-conductor layer 404 from the metallic wire 401, onto the MTJ stack 403. On the other hand, the electrically insulating spin-conductor layer 404 prevents electronic current (coming from the conductive via 402) from exiting the metallic wire 401 “prematurely”, such that majority of the electronic current may pass through the entire metallic wire 401 to generate perpendicular spins. At the second end 22 of the metallic wire 401, any remaining electronic current may be collected by the metal stud 406 and pass onto the MTJ stack 403 via the metallic spin-conductor layer 405.

As being described above and illustrated in their respective drawings, the MRAM device 100, 200, 300, and 400 achieve device performance improvement by placing the MTJ stack asymmetrically so as to collect one type, such as the upwardly type, of perpendicular spins more than the other type, such as the downwardly type, of perpendicular spins. In one embodiment, the asymmetrical placement enables the MTJ stack to collect one type of perpendicular spins and substantially avoid the other type of perpendicular spins.

Here it is to be noted that the metallic wires, conductive vias, and MTJ stacks of the MRAM devices 100, 200, 300, and 400 are generally embedded in one or more dielectric layers, although such dielectric layers may not be particularly illustrated in FIGS. 1, 2, 3, and 4 respectively. For example, the metallic wires 101, 201, 301, and 401 may be spin-orbit-torque (SOT) wires, and the first and the second side 11 and 12 and the first and the second end 21 and 22 of the metallic wires 101, 201, 301, and 401 are generally surrounded by a dielectric layer. Illustration of the dielectric layers are omitted for the simplicity of illustration in order not to obscure illustration of embodiments of present invention. Some dielectric layers may be omitted in illustration in the subsequent drawings of MRAM devices for the same reason.

FIGS. 5A, 5B, and 5C are demonstrative illustrations of a MRAM device according to one embodiment of present invention. More particularly, FIG. 5A is a front side view, FIG. 5B is a top view, and FIG. 5C is a left side view of a MRAM device 500. Similar to MRAM devices described above, the MRAM device 500 has a metallic wire 501 that has a width W between a first side 11 and a second side 12; a length L between a first end 21 and a second end 22; and a lengthwise axis 10. The metallic wire 501 is symmetric with respect to the lengthwise axis 10.

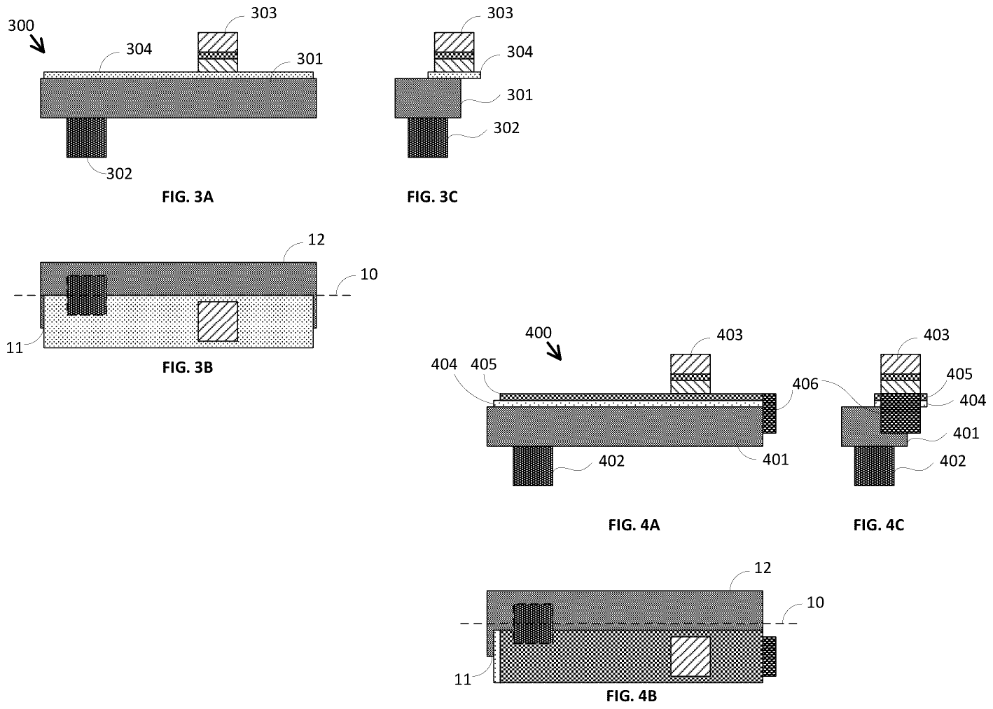

Here, the metallic wire 501 may be referred to as a first metallic wire. In addition to a conductive via 502 and a MTJ stack 503, the MRAM device 500 may include a second metallic wire 504. According to embodiments of present invention, structure asymmetry of the MRAM device 500 may be achieved by placing the second metallic wire 504 side-by-side with the first metallic wire 501, thereby forming a bimetallic wire. In other words, the second metallic wire 504 may be formed at or may be attached to the first side 11 of the first metallic wire 501. The first and the second metallic wire 501 and 504 together may be referenced to as a bimetallic wire. With the second metallic wire 504, the MRAM device 500 may be structurally asymmetric with respect to the lengthwise axis 10 of the first metallic wire 501. Here, although not required as being discussed below in more details with reference to FIGS. 6A-6D, in one embodiment, the MTJ stack 503 is placed on top of the metallic wire 501 and is placed symmetric with respect to the lengthwise axis 10.

In one embodiment, the first metallic wire 501 may include, or be made of, a first metal element whose atomic number is larger than 54, which may be known as “heavy” metal. The second metallic wire 504 may include, or be made of, a second metal element whose atomic number is less than 30, which may be known as “light” metal. In another embodiment, the first metallic wire 501 may be made of either tungsten (W), platinum (Pt), or tantalum (Ta), and the second metallic wire 504 may be made of either copper (Cu) or aluminum (Al).

According to embodiment of present invention, during normal operation, electronic current may flow from the conductive via 502 into the first metallic wire 501 towards the MTJ stack 503. Spins of electrons may be created or generated inside the first metallic wire 501 in a counterclockwise direction. More particularly, upwardly perpendicular spins may be created in an area close to the first side 11 of the first metallic wire 501.

By forming the second metallic wire 504 next to the first side of the first metallic wire 501, embodiments of present invention enables the transfer of those upwardly perpendicular spins at the first side 11 of the first metallic wire 501 onto the second metallic wire 504. Once being transferred onto the second metallic wire 504, the upwardly perpendicular spins may be more easily preserved inside the second metallic wire 504 which is a “light” metal, as being compared with if they were to remain inside the first metallic wire 501 which is a “heavy” metal, where the upwardly perpendicular spins may subject to spin-flip scattering. The upwardly perpendicular spins may propagate inside the second metallic wire 504 until they reach and are collected by the MTJ stack 503 down the metallic wire 501. As being described above, here a “light” metal means a metal element with a low atomic number of, for example, less than 30, while a “heavy” metal means a metal element with a high atomic number of, for example, larger than 54.

FIGS. 6A, 6B, 6C, and 6D are top views of MRAM devices according to some embodiments of present invention. More particularly, FIGS. 6A, 6B, 6C, and 6D illustrates a MRAM device 600 that has a first and a second metallic wire 601 and 604 but with different placement of a conductive via 602 and a MTJ stack 603. For example, the conductive via 602 may be placed solely inside the first metallic wire 601, as in FIG. 6A, 6C, and 6D, or over an interface area where the first metallic wire 601 meets the second metallic wire 604, as in FIG. 6B. Further for example, the MTJ stack 603 may be placed in the first metallic wire as previously illustrated in FIG. 5B or placed partially or entirely in the second metallic wire 604, as in FIG. 6A, 6B, 6C, and 6D. Moreover, the second metallic wire 604 maybe in an L-shape and is formed next to the first side 11 and the second end 22 of the first metallic wire 601 as is illustrated in FIG. 6C and 6D.

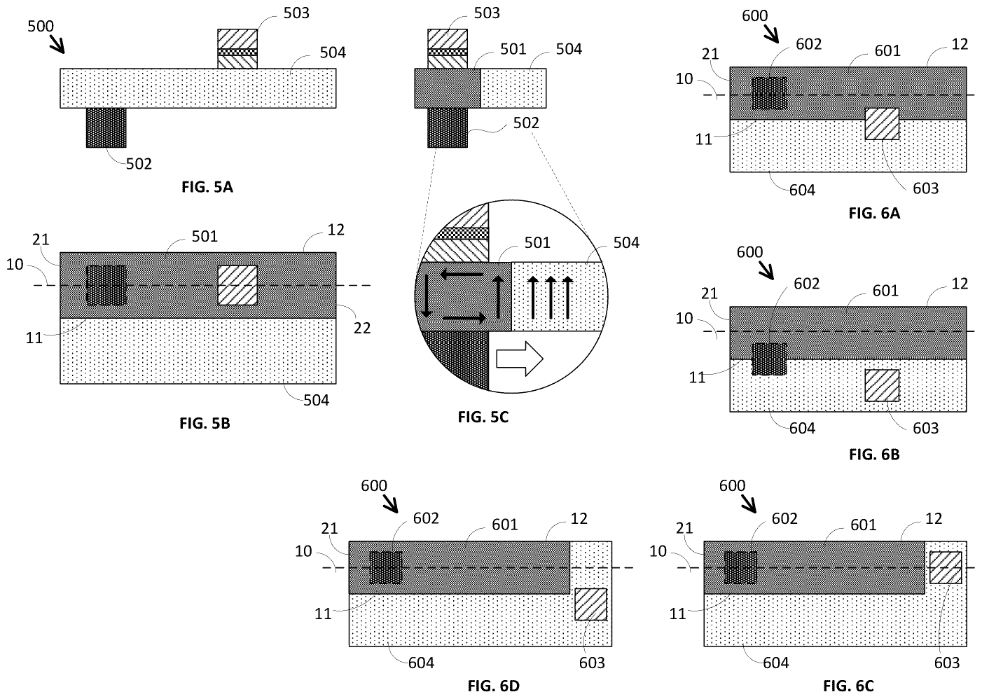

FIGS. 7A, 7B, and 7C are demonstrative illustrations of a MRAM device according to one embodiment of present invention. More particularly, FIG. 7A is a front side view, FIG. 7B is a top view, and FIG. 7C is a left side view of a MRAM device 700. Similar to MRAM devices described above, the MRAM device 700 has a metallic wire 701 that has a width W between a first side 11 and a second side 12; a length L between a first end 21 and a second end 22; and a lengthwise axis 10. The metallic wire 701 is symmetric with respect to the lengthwise axis 10.

Here the metallic wire 701 may be referred to as a first metallic wire. In addition to a conductive via 702 and a MTJ stack 703, the MRAM device 700 may include a second metallic wire 704. Similar to the MRAM device 500, the second metallic wire 704 may be placed at or attached to the first side 11 of the first metallic wire 701 to form a bimetallic wire. Different from the MRAM device 500, here the MTJ stack 703 is placed on top of an area around an interface between the first and the second metallic wire 701 and 704.

In one embodiment, the first metallic wire 701 and the second metallic wire 704 may include materials that will generate spin orbit torque of opposite signs when current flow through thereof in a same direction. For example, the first metallic wire 701 may be made of either tungsten (W) or tantalum (Ta), and the second metallic wire 704 may be made of niobium (Nb).

According to embodiment of present invention, during normal operation, electronic current may flow from the conductive via 702 into both the first metallic wire 701 and the second metallic wire 704 towards the MTJ stack 703. Counterclockwise spins of electrons may be created or generated inside the first metallic wire 701 and clockwise spins of electrons may be created or generated inside the second metallic wire 704, as is illustrated in the expanded drawing of FIG. 7C. By placing the MTJ stack 703 over the interface area between the first and the second metallic wire 701 and 704, embodiments of present invention enable a process to collect upwardly perpendicular spins generated both inside the first and the second metallic wire 701 and 704, enhancing performance of the MRAM device 700 with more upwardly perpendicular spins.

FIGS. 8A, 8B, and 8C are demonstrative illustrations of a MRAM device according to one embodiment of present invention. More particularly, FIG. 8A is a front side view, FIG. 8B is a top view, and FIG. 8C is a left side view of a MRAM device 800. Similar to MRAM devices described above, the MRAM device 800 has a metallic wire 801 that has a width W between a first side 11 and a second side 12; a length L between a first end 21 and a second end 22; and a lengthwise axis 10. The metallic wire 801 is symmetric with respect to the lengthwise axis 10.

Like the MRAM device 700, the MRAM device 800 includes both a first metallic wire 801 and a second metallic wire 804 that may generate spin orbit torque of opposite signs when current flow through thereof in a same direction. For example, the first metallic wire 801 may be W or Ta and the second metallic wire 804 may be Nb. The MRAM device 800 may further include, similar to the MRAM device 400, an electrically insulating spin-conductor layer 805 that covers an interface area approximate half of the first metallic wire 801 and half of the second metallic wire 804. The MRAM device 800 further includes a metallic spin-conductor layer 806 of low resistance, on top of the electrically insulating spin-conductor layer 805. A metal stud 807 may be formed at the end of the metallic spin-conductor layer 806. The metal stud 807 may contact the first and the second metallic wire 801 and 804 at their respective ends.

Like the electrically insulating spin-conductor layer 404, the electrically insulating spin-conductor layer 805 may be a layer of nickel-oxide (NiO) that has low “resistance” to spins of electrons but high resistance to electronic current. The metallic spin-conductor layer 806 may be a low resistance metallic layer, such as copper (Cu), that may pass perpendicular spins, collected from the first and the second metallic wire 801 and 804, via the electrically insulating spin-conductor layer 805, onto the MTJ stack 803. On the other hand, the electrically insulating spin-conductor layer 805 may guide or force at least most of the electronic current through the first and the second metallic wire 801 and 804, passing underneath the MTJ stack 803, until they reach the metal stud 807. At the metal stud 807, any remaining electronic current may be collected and passed onto the MTJ stack 803 via the metallic spin-conductor layer 806.

FIGS. 9A, 9B, and 9C are demonstrative illustrations of a MRAM device according to one embodiment of present invention. More particularly, FIG. 9A is a front side view, FIG. 9B is a top view, and FIG. 9C is a left side view of a MRAM device 900. Similar to MRAM devices described above, the MRAM device 900 has a metallic wire 901 that has a width W between a first side 11 and a second side 12; a length L between a first end 21 and a second end 22; and a lengthwise axis 10. The metallic wire 801 is symmetric with respect to the lengthwise axis 10.

Similar to the MRAM device 800, the MRAM device 900 includes both the first and a second metallic wire 901 and 904, a conductive via 902, a MTJ stack 903, an electrically insulating spin-conductor layer 905 and a metallic spin-conductor layer 906 on top of the electrically insulating spin-conductor layer 905. Different from the MRAM device 800, the electrically insulating spin-conductor layer 905 of the MRAM device 900 terminates before reaching to an area directly underneath the MTJ stack 903. Electronic current may be guided or forced by the electrically insulating spin-conductor layer 905 to flow to the area underneath the MTJ stack 903, and then directly pass through the metallic spin-conductor layer 906 into the MTJ stack 903. Because of that, no metal stud may be used or becomes necessary at the end of the metallic spin-conductor layer 906 to collect any remaining electronic current.

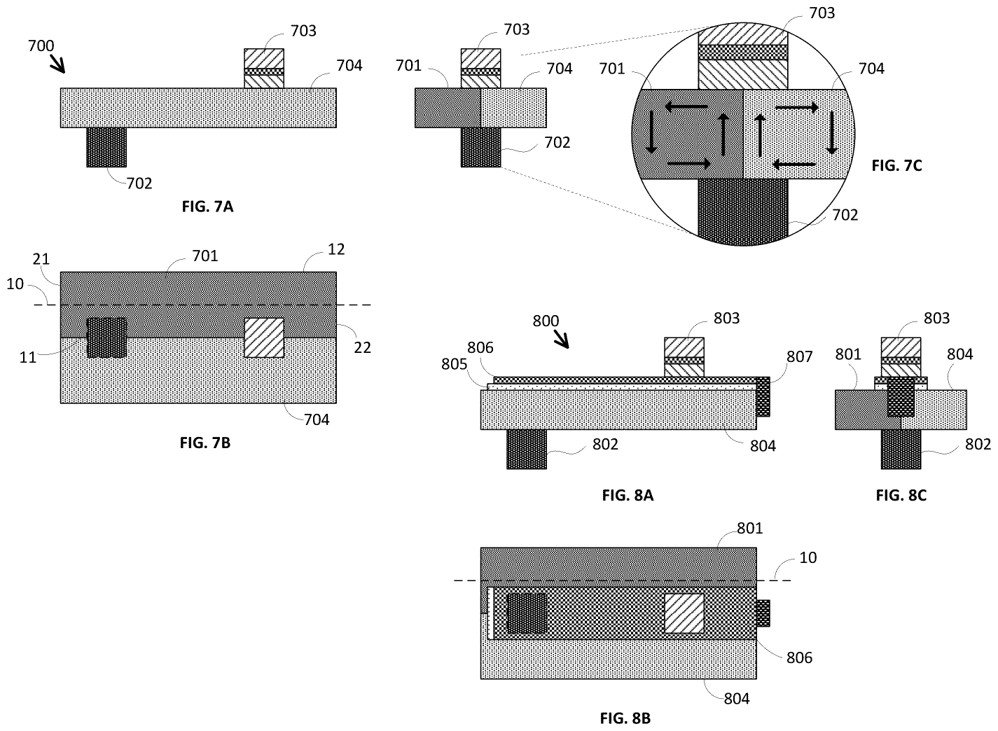

FIGS. 10A, 10B, and 10C are side views of MRAM devices according to some embodiments of present invention. More particularly, FIG. 10A illustrates a MRAM device 1000 where a conductive via 1002 may be formed on top of a metallic wire 1001 while a MTJ stack 1003 may be formed underneath the metallic wire 1001; FIG. 10B illustrates a MRAM device 1000 where a conductive via 1002 and a MTJ stack 1003 are both formed on top of a metallic wire 1001; and FIG. 10C illustrates a MRAM device 1000 where a MTJ stack 1003 is formed on top of a metallic wire 1001 via a low resistance via 1004.

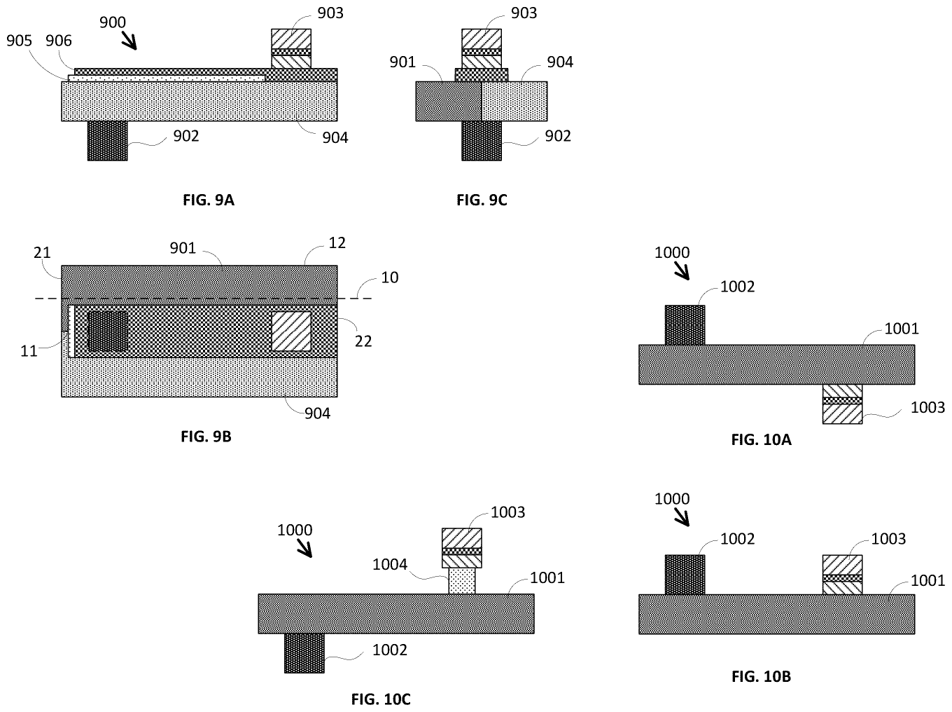

FIGS. 11A, 11B, and 11C are top views of MRAM devices according to some embodiments of present invention. For example, FIG. 11A illustrates a MRAM device 1100 that has a non-straight metallic wire 1101. The metallic wire 1101 may be formed in a shape of character “C” in order to save some real estate space. The MRAM device 1100 may also include a conductive via 1102, a MTJ stack 1103, and optionally a high resistance spin-conductor layer 1104 covering an edge portion of the metallic wire 1101. The high resistance spin-conductor layer 1104 may be a layer of graphene formed through a CVD process or may be a layer of “dirty” copper as is defined above. Further for example, FIG. 11B illustrates a MRAM device 1100 that has a non-straight metallic wire 1101 in a shape of the character “S” in order to save some real estate space as in FIG. 11A. FIG. 11C illustrates a MRAM device 1100 that has a non-uniform high resistance spin-conductor layer 1104 covering different portions of a metallic wire 1101. A conductive via 1102 may be placed partially above high resistance spin-conductor layer 1104, while a MTJ stack 1103 may be formed or placed entirely on top of the high resistance spin-conductor layer 1104 in an expanded area thereof.

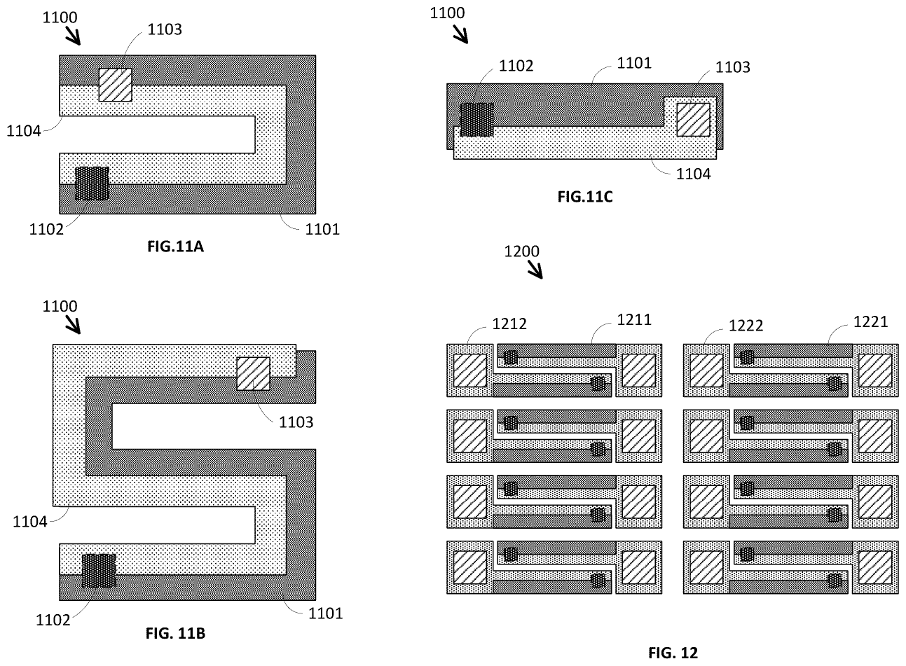

FIG. 12 is a top view of a MRAM device according to one embodiment of present invention. More particularly, FIG. 12 illustrates a MRAM structure 1200 that includes multiple MRAM devices such as MRAM device 1211, 1212, 1221, and 1222 that are arranged together forming the MRAM structure 1200. The multiple MRAM devices, such as the MRAM device 1211, 1212, 1221, and 1222 may be any one or more of the MRAM devices 100, 200, 300, 400, 500, 600, 700, 800, 900, 1000, and 1100 as being described above, and may be individually operated or operable, or may be collectively controlled to jointly achieve a desired data storage function.

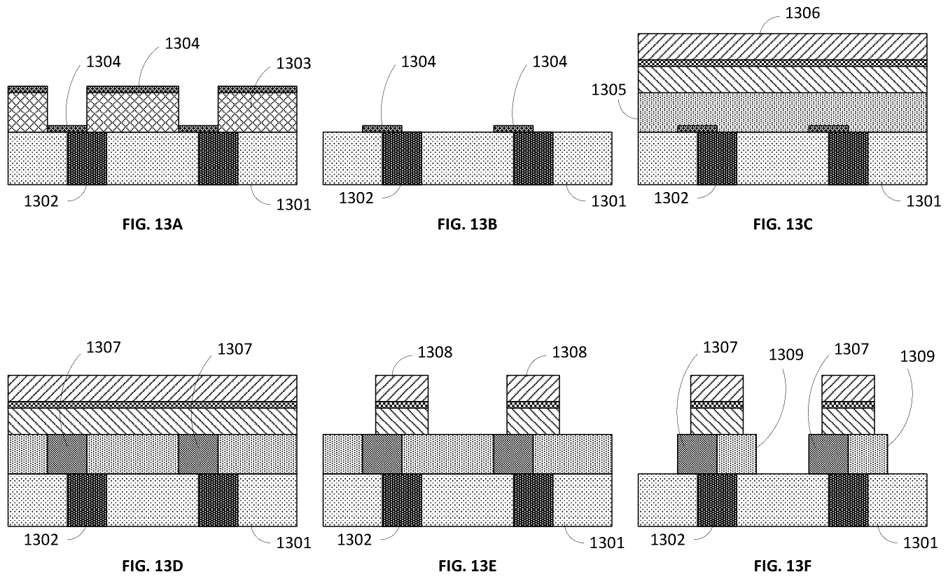

The MRAM devices described above may be formed or manufactured using lithographic patterning and etching process which may include, for example, subtractive and additive patterning processes. For example, FIG. 13A-13E are demonstrative illustrations of cross-sectional views of a MRAM device at various manufacturing steps according to one embodiment of present invention. For example, embodiments of present invention may include providing a semiconductor substrate 1301 with one or more conductive vias 1302 embedded or formed therein. A hard mask 1303 may be formed on top of the substrate 1301 with openings to expose a portion of the one or more conductive vias 1302. A seed layer 1304 may then be directionally deposited inside the openings (FIG. 13A). Next, the hard mask 1303 may be removed or lifted, leaving only the seed layer 1304 inside the openings remaining on top of the one or more conductive vias 1302 (FIG. 13B). A spin-conducting material layer 1305 may subsequently be deposited on top of the seed layer 1304, and layers of ferromagnetic material 1306 (for forming the MTJ stacks) may be deposited or formed on top of the spin-conducting material layer 1305 (FIG. 13C). The structure is then subjected to an annealing process which transforms the seed layer 1304 into one or more SOT wires 1307 (FIG. 13D). The layers of ferromagnetic material 1306 on top of the SOT wires 1307 are then patterned to form one or more MTJ stacks 1308 (FIG. 13E). Thereafter, the spin-conducting material layer 1305 may be patterned into one or more metallic wires 1309, such as spin-conductor wires, that are formed next to the one or more SOT wires 1307 (FIG. 13F).

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A MRAM structure comprising:
a metallic wire, the metallic wire having a width between a first side and a second side; a length between a first end and a second end; and a lengthwise axis, and being symmetric with respect to the lengthwise axis;
a conductive via contacting a first area of the metallic wire; and
a magnetic tunnel junction (MTJ) stack placed at a second area of the metallic wire,
wherein the MRAM structure is asymmetric with respect to the lengthwise axis.

2. The MRAM structure of claim 1, wherein the metallic wire is a first metallic wire, further comprising a second metallic wire next to the first side of the first metallic wire.

3. The MRAM structure of claim 2, wherein the first metallic wire comprises a metal having an atomic number greater than 54, and the second metallic wire comprises a metal having an atomic number less than 30.

4. The MRAM structure of claim 2, wherein the first metallic wire is made of a material selected from a group consisting of tungsten (W), platinum (Pt), and tantalum (Ta), and the second metallic wire is made of a material selected from a group consisting of aluminum (Al) and copper (Cu).

5. The MRAM structure of claim 3, wherein the MTJ stack includes a free layer, a tunnel barrier layer on top of the free layer, and a reference layer on top of the tunnel barrier layer, wherein the free layer is placed on at least one of the first and the second metallic wire.

6. The MRAM structure of claim 2, wherein the first metallic wire comprises tungsten (W), platinum (Pt), or tantalum (Ta), and the second metallic wire comprises niobium (Nb).

7. The MRAM structure of claim 6, further comprising an electrically insulating spin-conductor on top of the first and the second metallic wire, and a metallic spin-conductor on top of the electrically insulating spin-conductor, wherein the electrically insulating spin-conductor covers a portion of the first metallic wire and a portion of the second metallic wire that is adjacent to the portion of the first metallic wire.

8. The MRAM structure of claim 7, wherein the MTJ stack is placed above the metallic spin-conductor and a portion of the metallic spin-conductor underneath the MTJ stack is in direct contact with the first and the second metallic wire.

9. The MRAM structure of claim 7, further comprising a metallic stud at an end of the metallic spin-conductor, wherein the metallic stud contacts the metallic spin-conductor; the first metallic wire; and the second metallic wire.

10. The MRAM structure of claim 7, wherein the electrically insulating spin-conductor comprises nickel oxide (NiO) and the metallic spin-conductor comprises copper (Cu).

11. The MRAM structure of claim 1, wherein the conductive via and the MTJ stack are symmetrically placed with respect to the lengthwise axis of the metallic wire.

12. The MRAM structure of claim 1, wherein the MTJ stack is placed substantially close to or over an edge at the first side of the metallic wire and covers less than one half of the width of the metallic wire.

13. The MRAM structure of claim 12, wherein the metallic wire is embedded in a dielectric layer, the dielectric layer covering the first and the second side of the metallic wire.

14. The MRAM structure of claim 12, further comprising an electrically insulating spin-conductor and a metallic spin-conductor on top of the electrically insulating spin-conductor, the electrically insulating spin-conductor covering the edge at the first side of the metallic wire.

15. The MRAM structure of claim 12, further comprising a high resistance spin-conductor covering the edge at the first side of the metallic wire.

16. The MRAM structure of claim 1, wherein the metallic wire is not straight and includes one or more bends from the first end to the second end.

17. A MRAM structure comprising:
a bimetallic wire having a first and a second metallic wire formed side-by-side;
a conductive via contacting a first area of the bimetallic wire; and
a magnetic tunnel junction (MTJ) stack contacting a second area of the bimetallic wire,
wherein the first metallic wire comprises a first metal element having an atomic number greater than 54, and the second metallic wire comprises a second metal element having an atomic number less than 30.

18. The MRAM structure of claim 17, wherein the conductive via is placed on the first metallic wire, and the MTJ stack is placed on the second metallic wire.

19. A MRAM structure comprising:
a bimetallic wire having a first and a second metallic wire formed side-by-side;
a conductive via contacting a first area of the bimetallic wire; and
a magnetic tunnel junction (MTJ) stack contacting a second area of the bimetallic wire,
wherein the first metallic wire is made of tungsten (W), platinum (Pt), or tantalum (Ta), and the second metallic wire is made of copper (Cu) or aluminum (Al).

20. The MRAM structure of claim 19, wherein the MTJ stack is placed over an interface between the first metallic wire and the second metallic area.
